(19) United States
(12) Patent Application Publication
(10) Pub. No.: US 2015/0200111 A1
(43) Pub. Date: Jul. 16, 2015

(54) PLANARIZATION SCHEME FOR FINFET GATE HEIGHT UNIFORMITY CONTROL

(71) Applicant: GLOBALFOUNDRIES Inc., Grand Cayman (KY)

(72) Inventors: Sruthi Muralidharan, Troy, NY (US); Zhenyu Hu, Clifton Park, NY (US); Qi Zhang, Mechanicville, NY (US); Ja-Hyung Han, Clifton Park, NY (US); Dinesh Koli, Clifton Park, NY (US); Zhuangfei Chen, Clifton Park, NY (US)

(73) Assignee: GLOBALFOUNDRIES Inc., Grand Cayman (KY)

(21) Appl. No.: 14/153,120

(22) Filed: Jan. 13, 2014

(51) Int. Cl. H01L 21/321; H01L 21/02; H01L 21/265

(52) U.S. Cl. CPC H01L 21/3212; H01L 21/26566; H01L 21/0234; H01L 21/02164; H01L 21/02532

(57) ABSTRACT

Embodiments of the present invention provide improved methods for fabrication of finFETs. During finFET fabrication, a film, such as amorphous silicon, is deposited on a semiconductor substrate which has regions with fins and regions without fins. A fill layer is deposited on the film and planarized to form a flush surface. A recess or etch process is used to form a planar surface with all portions of the fill layer removed. A finishing process such as a gas cluster ion beam process may be used to further smooth the substrate surface. This results in a film having a very uniform thickness across the structure (e.g. a semiconductor wafer), resulting in improved within-wafer (WiW) uniformity and improved within-chip (WiC) uniformity.

### FIELD OF THE INVENTION

The present invention relates generally to semiconductor fabrication, and more particularly to methods for achieving gate height uniformity in finFETs.

### BACKGROUND

As integrated circuits continue to scale downward in size, the finFET (fin field effect transistor) is becoming an attractive device for use in semiconductor integrated circuits (ICs). In a finFET, the channel is formed by a semiconductor vertical fin, and a gate electrode is located and wrapped around the vertical fin. With finFETs, as with other transistor types, device variability is something that needs to be constrained to acceptable limits in order to produce reliable integrated circuits and maintain acceptable product yield. It is therefore desirable to have improvements in the fabrication of finFET transistors to reduce the device variability.

### SUMMARY

In general, embodiments of the present invention provide improved methods for fabrication of finFETs. During finFet fabrication, a film, such as amorphous silicon, is deposited on a semiconductor substrate which has regions with fins and regions without fins. A fill layer is deposited on the film and planarized to form a flush surface. A recess or etch process is used to form a planar surface with all portions of the fill layer removed. A finishing process such as a gas cluster ion beam process may be used to further smooth the substrate surface. This results in a film having a very uniform thickness across the structure (e.g., a semiconductor wafer), resulting in improved within-wafer (WiW) uniformity and improved within-chip (WiC) uniformity.

In a first aspect, embodiments of the present invention provide a method of forming a semiconductor structure, comprising: depositing a film on a semiconductor substrate, wherein the semiconductor substrate comprises a plurality of fins formed thereon; depositing a fill layer on the film; planarizing the fill layer to be flush with the film; and performing an etch on the semiconductor structure.

In a second aspect, embodiments of the present invention provide a method of forming a semiconductor structure, comprising: depositing an amorphous silicon film having a thickness ranging from about 120 nanometers to about 150 nanometers on a semiconductor substrate, wherein the semiconductor substrate comprises a plurality of fins formed thereon; depositing a fill layer on the amorphous silicon film; planarizing the fill layer to be flush with the amorphous silicon film; and performing an etch on the semiconductor structure.

In a third aspect, embodiments of the present invention provide a method of forming a semiconductor structure, comprising: depositing a film on a semiconductor substrate, wherein the semiconductor substrate comprises a plurality of fins formed thereon; depositing a fill layer on the film; performing a first planarization on the fill layer to planarize the fill layer to be flush with the film; and performing a non-selective etch on the semiconductor structure.

### BRIEF DESCRIPTION OF THE DRAWINGS

The accompanying drawings, which are incorporated in and constitute a part of this specification, illustrate several embodiments of the present teachings and, together with the description, serve to explain the principles of the present teachings.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG). Furthermore, for clarity, some reference numbers may be omitted in certain drawings.

FIG. 1 is a semiconductor structure at a starting point for illustrative embodiments of the present invention.

FIG. 2 is a semiconductor structure after a subsequent process step of depositing a film on the semiconductor substrate, in accordance with illustrative embodiments.

FIG. 3 is a semiconductor structure after a subsequent process step of depositing a fill layer on the film, in accordance with illustrative embodiments.

FIG. 4 is a semiconductor structure after a subsequent process step of planarizing the semiconductor structure, in accordance with illustrative embodiments.

FIG. 5 is a semiconductor structure after a subsequent process step of performing an etch on the semiconductor structure, in accordance with illustrative embodiments.

FIG. 6 is a semiconductor structure after a subsequent process step of performing a gas cluster ion beam process, in accordance with illustrative embodiments.

FIG. 7 is a flowchart indicating process steps for illustrative embodiments of the present invention.

### DETAILED DESCRIPTION

Embodiments of the present invention provide improved methods for fabrication of finFETs. During finFET fabrication, a film, such as amorphous silicon, is deposited on a semiconductor substrate which has regions with fins and regions without fins. Due to the loading effect of the fins, even after a planarization process, the deposited film is not completely planar. A fill layer is deposited on the film and planarized to form a flush surface. A recess or etch process is used to form a planar surface with all portions of the fill layer removed. A finishing process such as a gas cluster ion beam process may be used to further smooth the substrate surface. This results in a film having a very uniform thickness across the structure (e.g., a semiconductor wafer), resulting in improved within-wafer (WiW) uniformity and improved within-chip (WiC) uniformity. The improved WiW and WiC uniformities can result in improved product yield.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g., a second layer), wherein intervening elements, such as an interface structure (e.g., interface layer), may be present between the first element and the second element.

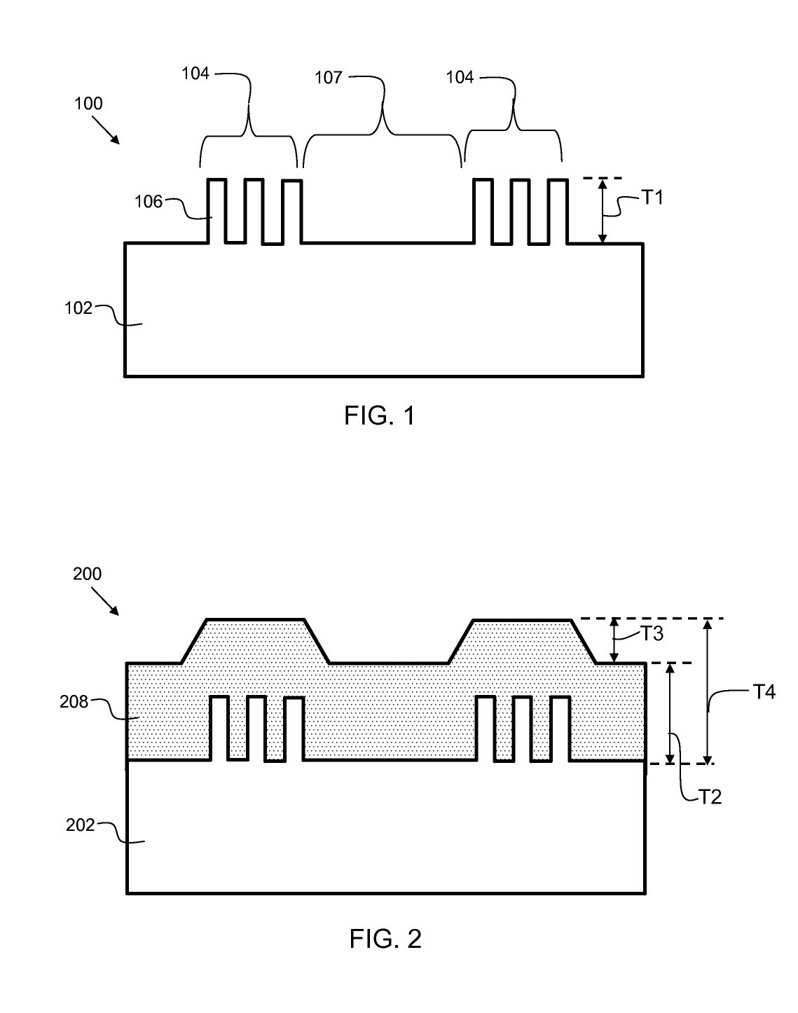

FIG. 1 shows a semiconductor structure 100 at a starting point for illustrative embodiments. Semiconductor structure 100 comprises substrate 102. In embodiments, substrate 102 may comprise a bulk substrate, such as a silicon wafer. In other embodiments, substrate 102 may comprise a silicon-on-insulator (SOI) substrate that is disposed on an insulating layer (not shown), which is in turn disposed on a bulk substrate (not shown). Embodiments of the present invention may be used with both bulk and SOI type finFETs. Multiple fin regions 104 are formed on the substrate 102. Each fin region 104 comprises one or more fins 106. The areas of substrate 102 where there are no fins or other features of significant height are base regions, such as indicated by reference 107. The fins 106 have a height T1, and in embodiments, T1 ranges from about 25 nanometers to about 40 nanometers.

FIG. 2 is a semiconductor structure 200 after a subsequent process step of depositing a film 208 on the semiconductor substrate 202, in accordance with illustrative embodiments. As stated previously, similar elements may be referred to by similar numbers in various figures (FIGs) of the drawing, in which case typically the last two significant digits may be the same. For example, semiconductor substrate 202 of FIG. 2 is similar to semiconductor substrate 102 of FIG. 1. In embodiments, film 208 may comprise amorphous silicon (a-Si), and may be deposited via a furnace deposition. The (a-Si) film may serve as a finFET gate, or as a dummy gate in a replacement metal gate (RMG) process. Hence, it is important to have a consistent thickness for film 208. However, due to the conformal deposition, the portions of film 208 disposed over the fin regions (104 of FIG. 1) are higher than the portions of film 208 disposed over base regions (107 of FIG. 1). The film 208 has a height T2 over base regions, and an additional height T3 over fin regions. In some embodiments, T2 may range from about 120 nanometers to about 150 nanometers. The maximum height of the film is T4, where T4=T2+T3, and the minimum height of the film is T2. Therefore the film 208 is non-planar. A chemical mechanical polish (CMP) process may be used to reduce the height of T3. However, the CMP may introduce non-uniformities due to the loading effect of the fin regions, and so in practice, T3 may range from about 20 nanometers to about 30 nanometers, and it is difficult to mechanically grind away that material without introducing within-wafer (WiW) non-uniformities. With the steps of the exemplary embodiments that follow, this problem is mitigated.

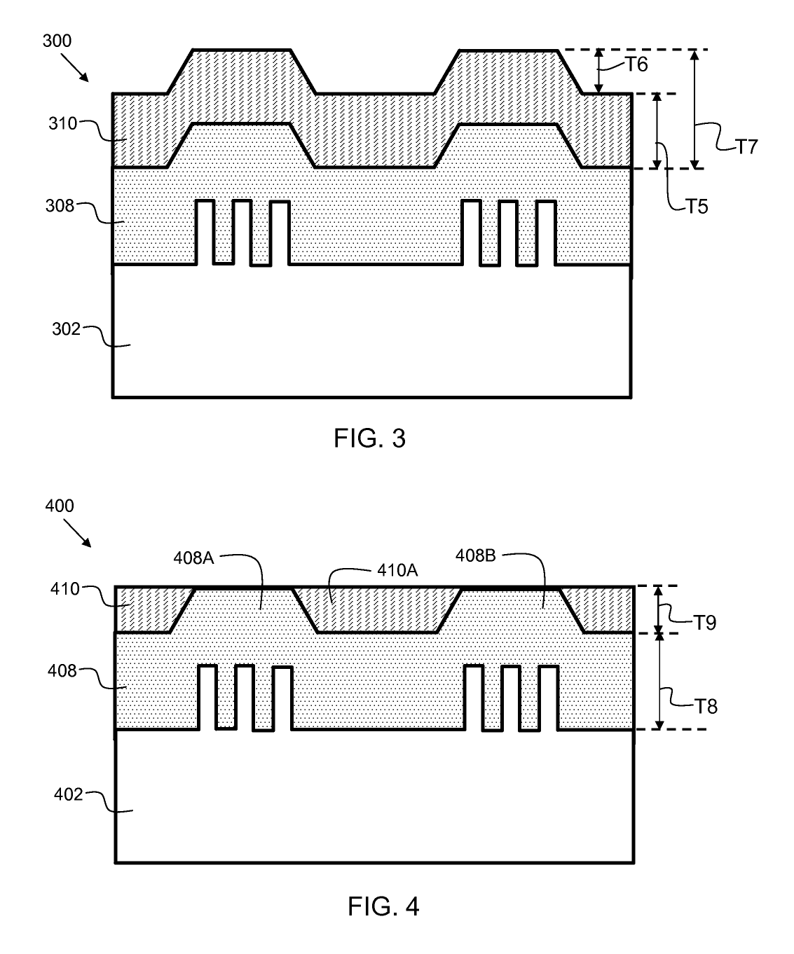

FIG. 3 is a semiconductor structure 300 after a subsequent process step of depositing a fill layer 310 on the film 308, in accordance with illustrative embodiments. In embodiments, fill layer 310 comprises an oxide, such as silicon oxide. In some embodiments, fill layer 310 comprises a high density plasma (HDP) silicon oxide. In some embodiments, a HDP silicon oxide is deposited via a chemical vapor deposition process. The fill layer 310 has a top contour similar to that of film 308. Hence, fill layer 310 has a height T5 over base regions, and an additional height T6 over fin regions. In embodiments, the height T5 ranges from about 90 nanometers to about 110 nanometers. The maximum height of the fill layer is T7, where T7=T5+T6, and the minimum height of the fill layer is T5. Therefore the fill layer 310 is non-planar.

FIG. 4 is a semiconductor structure 400 after a subsequent process step of planarizing the semiconductor structure, in accordance with illustrative embodiments. In embodiments, the planarization is performed with a chemical mechanical polish (CMP) process that stops on the amorphous silicon film 408. As a result of the planarization, the fill layer 410 is planarized to the level of film 408, and hence, the fill layer 410 is flush with the film 408. The top surface of the semiconductor structure 400 is now planar, and includes film regions 408A and 408B, with a fill layer region 410A disposed between film region 408A and film region 408B. The film 408 has a minimum thickness of T8, and the fill layer has a maximum thickness T9. In embodiments, T8 may range from about 120 nanometers to about 150 nanometers. In embodiments, T9 may range from about 90 nanometers to about 110 nanometers.

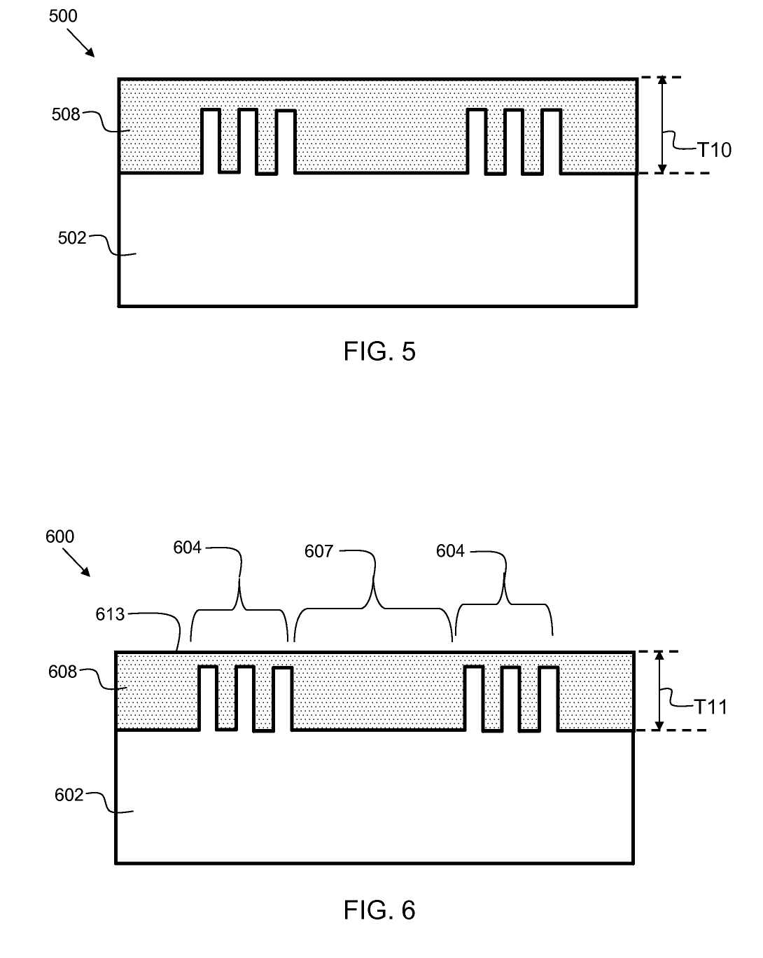

FIG. 5 is a semiconductor structure 500 after a subsequent process step of performing an etch or recess on the semiconductor structure, in accordance with illustrative embodiments. Preferably, the etch or recess process is non-selective, such that the process removes the film and the fill layer at an identical rate. Embodiments utilize an amorphous silicon film and a HDP oxide fill layer, and a reactive ion etch (RIE) process is used to remove the fill layer. The RIE process may be non-selective, such that the structure 500 remains planar. As a result of this process step, the fill layer is completely removed, and the remaining film 508 is planar, and has a thickness T10. In embodiments, T10 ranges from about 110 nanometers to about 140 nanometers.

FIG. 6 is a semiconductor structure 600 after a subsequent process step of performing a gas cluster ion beam process, in accordance with illustrative embodiments. A Gas Cluster Ion Beam (GCIB) tool has the capability to smooth surfaces on a nano scale. It can smooth a wide variety of surface material types to within an angstrom of roughness without damage to the substrate. The GCIB tool can smooth out slight variations in the thickness of film 608 due to imperfections in the preceding etch process. In practice, the etch or recess described in FIG. 5 may not be 100 percent non-selective, which causes non-uniformities in the height of the film. The GCIB process removes those non-uniformities. Therefore the top surface 613 is planar, having the same thickness T11 in both in the base region 607 and in the fin regions 604, thereby mitigating the loading effect. Embodiments of the present invention serve to improve within wafer uniformity and within chip uniformity, and results in integrated circuits with reduced variability. In practice, film 608 may be replaced as part of a replacement metal gate process. Forming a planar film 608 reduces the opportunities for over-etching and over-polishing that can adversely impact product yield.

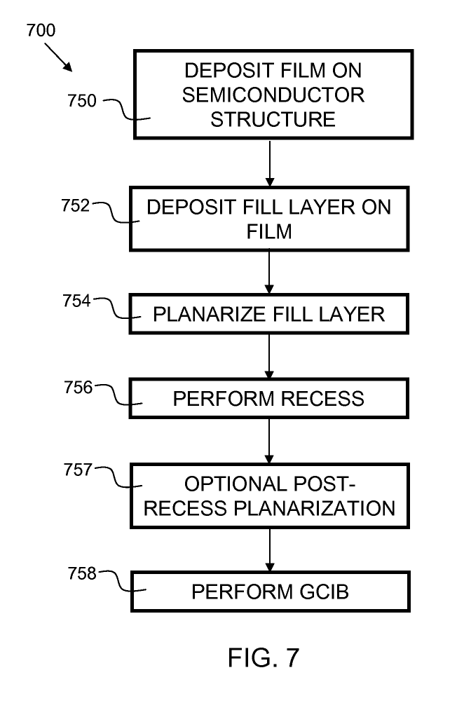

FIG. 7 is a flowchart 700 indicating process steps for illustrative embodiments of the present invention. In process step 750, a film is deposited on a semiconductor substrate. In embodiments, the semiconductor substrate is a bulk substrate. In other embodiments, the semiconductor substrate is a SOI substrate. The semiconductor substrate may be a silicon substrate. Other semiconductor materials may also be used for the semiconductor substrate. In embodiments, the film is comprised of amorphous silicon, and may be deposited via chemical vapor deposition. In process step 752, a fill layer is deposited on the film. In embodiments, the fill layer is a high density plasma (HDP) oxide, and may be deposited via chemical vapor deposition. In process step 754, the fill layer is planarized. In embodiments, a chemical mechanical polish (CMP) process is used for this step. In embodiments, the CMP process is a fixed abrasion CMP process. In process step 756, a recess is performed. In embodiments, the recess may comprise a reactive ion etch (RIE). The RIE may be a non-selective etch that etches the film and the fill layer at a similar rate. In process step 757, optionally, a post-recess planarization may be performed. In embodiments, the post-recess planarization is performed with a CMP process. The post-recess planarization may be useful in situations where the recess performed in process step 756 is not completely non-selective. In this case, the post-recess planarization can serve to reduce non-uniformities induced in the recess step. In some embodiments, the post-recess planarization is configured to remove an amount of amorphous silicon film ranging from about 30 nanometers to about 35 nanometers. In process step 858, a gas cluster ion beam (GCIB) process may be performed on the semiconductor structure. In embodiments, an argon cluster may be used with a cluster size ranging from about 1000 atoms per cluster to about 2000 atoms per cluster. In some embodiments, the GCIB process is configured to remove an amount of amorphous silicon film ranging from about 5 nanometers to about 10 nanometers. Note that some embodiments may use the planarization of process step 754 and the post-recess planarization of process step 757. Other embodiments may omit the post-recess planarization process 757.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A method of forming a semiconductor structure, comprising:
depositing a film on a semiconductor substrate, wherein the semiconductor substrate comprises a plurality of fins formed thereon;
depositing a fill layer on the film;
planarizing the fill layer to be flush with the film; and
performing an etch on the semiconductor structure.

2. The method of claim 1, further comprising performing a gas cluster ion beam process on the semiconductor structure.

3. The method of claim 2, further comprising performing a second planarization prior to performing the gas cluster ion beam process.

4. The method of claim 3, wherein performing the second planarization comprises performing a chemical mechanical polish process.

5. The method of claim 1, wherein depositing a film comprises depositing an amorphous silicon film.

6. The method of claim 5, wherein depositing a fill layer comprises depositing a silicon oxide layer.

7. The method of claim 6, wherein depositing a silicon oxide layer comprises depositing a high density plasma oxide.

8. The method of claim 1, wherein performing an etch comprises performing a reactive ion etch.

9. A method of forming a semiconductor structure, comprising:
depositing an amorphous silicon film having a thickness ranging from about 120 nanometers to about 150 nanometers on a semiconductor substrate, wherein the semiconductor substrate comprises a plurality of fins formed thereon;
depositing a fill layer on the amorphous silicon film;
planarizing the fill layer to be flush with the amorphous silicon film; and
performing an etch on the semiconductor structure.

10. The method of claim 9, wherein depositing a fill layer comprises depositing a high density plasma silicon oxide layer having a thickness ranging from about 90 nanometers to about 110 nanometers.

11. The method of claim 9, further comprising performing a gas cluster ion beam process on the semiconductor structure.

12. The method of claim 11, further comprising performing a second planarization prior to performing the gas cluster ion beam process.

13. The method of claim 12, wherein the second planarization comprises a chemical mechanical polish, and wherein the second planarization is configured to remove an amount of the amorphous silicon film ranging from about 30 nanometers to about 35 nanometers.

14. The method of claim 11, wherein the gas cluster ion beam process is configured to remove an amount of the amorphous silicon film ranging from about 5 nanometers to about 10 nanometers.

15. A method of forming a semiconductor structure, comprising:
depositing a film on a semiconductor substrate, wherein the semiconductor substrate comprises a plurality of fins formed thereon;
depositing a fill layer on the film;
performing a first planarization on the fill layer to planarize the fill layer to be flush with the film; and
performing a non-selective etch on the semiconductor structure.

16. The method of claim 15, further comprising performing a gas cluster ion beam process on the semiconductor structure.

17. The method of claim 16, further comprising performing a second planarization prior to performing the gas cluster ion beam process.

18. The method of claim 17, wherein performing the third planarization comprises performing a chemical mechanical polish process.

19. The method of claim 15, wherein depositing a film comprises depositing an amorphous silicon film.

20. The method of claim 15, wherein depositing a fill layer comprises depositing a high density plasma silicon oxide layer.
